(19) United States
(12) Patent Application Publication
(10) Pub. No.: US 2005/0260528 A1
(43) Pub. Date: Nov. 24, 2005

(54) Liquid composition for immersion lithography and lithography method using the same

(75) Inventors: Keun Kyu Kong, Gyeonggi-do (KR); Hyoung Ryeun Kim, Gyeonggi-do (KR); Hyeong Soo Kim, Gyeonggi-do (KR); Jae Chang Jung, Seoul (KR); Sung Koo Lee, Seoul (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Gyeonggi-do (KR)

(21) Appl. No.: 10/999,528

(22) Filed: Nov. 30, 2004

(30) Foreign Application Priority Data
May 22, 2004 (KR) KR10-2004-0036609
Jul. 2, 2004 (KR) KR10-2004-0051501
Jul. 2, 2004 (KR) KR10-2004-0051502
Jul. 2, 2004 (KR) KR10-2004-0051503

(51) Int. Cl. G03F 7/00

(52) U.S. Cl. 430/322; 430/449

(57) ABSTRACT

Disclosed herein are a liquid composition for immersion lithography and a lithography method using the composition. The liquid composition includes at least one nonionic surfactant selected from the group comprising of a polyvinyl alcohol, a pentaerythritol-based compound, a polymer containing an alkylene oxide, and a compound represented by Formula I: 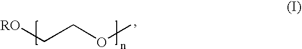
wherein R is a linear or branched, substituted C₁-C₄₀ alkyl, and n is an integer ranging from 10 to 10,000. The surface tension of the liquid composition is reduced by the nonionic surfactant, thereby solving the problem that the liquid composition is not completely filled or is partially concentrated on a wafer having a fine topology and removing micro bubbles between the photoresist film and the liquid composition.

### BACKGROUND OF THE DISCLOSURE

1. Field of the Disclosure

The present invention relates to a liquid composition for immersion lithography and a lithography method, and more specifically, to a liquid composition for immersion lithography in a lithography process for development of devices of less than 50 nanometers (nm) and a lithography method using the same.

2. Description of the Related Technology

The lithography process currently used is a dry lithography type that uses an exposure system for filling air between an exposure lens and a wafer.

In case of the dry lithography process, a new exposure system for development of 50 nm devices uses F₂ laser or an extreme ultraviolet (EUV) laser as a light source. As a result, the F₂ laser causes a problem in development of pellicles and the EUV laser causes a problem in development of masks and light sources, thereby having a disadvantage in mass production of the device.

In order to solve the above-described problems, an immersion lithography process has been developed as a noble lithography process.

The immersion lithography improves a resolving power by disposing a liquid between a final projection lens and a wafer, and increasing the numerical aperture (hereinafter, abbreviated as “NA”) of the optics system corresponding to a refractive index of the liquid. Here, the light source transmitted from the liquid has its actual wavelength corresponding to a value obtained by dividing a wavelength in air by a refractive index of a corresponding medium. Thus, for example, when passing light having a wavelength of 193 nm (ArF laser) through a medium of water, the wavelength of the ArF laser exiting the medium decreases from 193 nm to 134 nm (based on the refraction index of water being 1.44), resulting in the same effect of a shorter light source, such as the F₂ laser (157 nm).

FIG. 1 is a graph illustrating advantageous points of an immersion exposer. As shown, when the NA is fixed in a given pitch, a depth of focus (hereinafter, abbreviated as “DOF”) is shown to increase. When the NA increases larger than 1, the resolving power of the lens is improved.

For development of 50 nm devices, a liquid composition for immersion lithography is required to use the above-described immersion lithography process. Herein, the liquid composition for immersion lithography should completely cover a fine-topology surface of the wafer, and micro bubbles should be completely removed between the photoresist film and the liquid composition.

FIG. 2 is a cross-sectional diagram of an example illustrating a problem in a conventional immersion lithography process. When a liquid composition 20 for immersion lithography is applied on a wafer 10 having a fine topology, FIG. 2 shows that the liquid composition 20 is not completely filled on the fine topology of the wafer 10 (represented by “A”).

Because those portions not filled with the liquid composition are instead filled with air, the resolving power of patterns is severely degraded due to a difference in the refractive indices of the liquid composition and air.

### SUMMARY OF THE DISCLOSURE

Disclosed herein is a liquid composition for immersion lithography. The composition includes a main element and an additive, wherein the main element is water, and the additive is a nonionic surfactant preferably selected from the group consisting of a polyvinyl alcohol, a pentaerythritol-based compound, a polymer containing an alkylene oxide, a compound represented by Formula I below, and mixtures thereof. The compound of Formula I is: 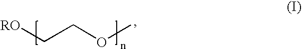
wherein R is a linear or branched, substituted C₁-C₄₀ alkyl, and n is an integer ranging from 10 to 10,000.

Also disclosed herein is a method of fabricating a semiconductor device. The method includes providing a wafer, forming a photoresist film on the wafer, exposing the photoresist film using the aforementioned, nonionic surfactant-containing liquid composition, and developing the exposed photoresist film to obtain a photoresist pattern.

### BRIEF DESCRIPTION OF THE DRAWINGS

For a more complete understanding of the invention, reference should be made to the following detailed description and accompanying drawings wherein:

FIG. 1 is a graph illustrating advantageous points of an immersion exposer;

FIG. 2 is a cross-sectional diagram of an example illustrating a problem in a conventional immersion lithography process;

FIG. 3a is a cross-sectional diagram illustrating a bath-type immersion lithography device according to an embodiment of the present invention;

FIG. 3b is a cross-sectional diagram illustrating a shower-type immersion lithography device according to an embodiment of the present invention; and,

FIG. 3c is a cross-sectional diagram illustrating a submarine-type immersion lithography device according to an embodiment of the present invention.

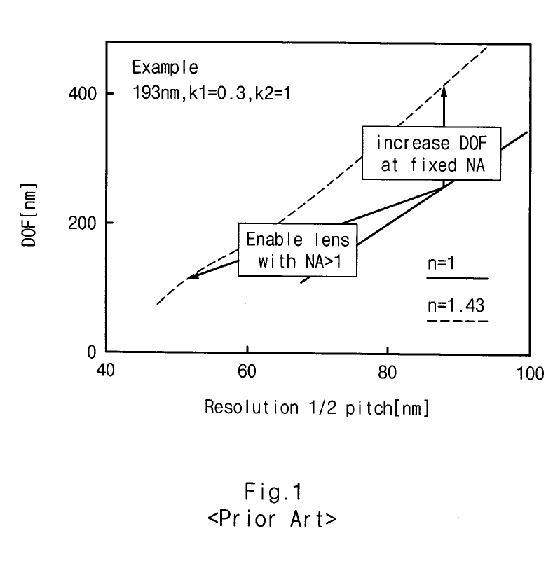

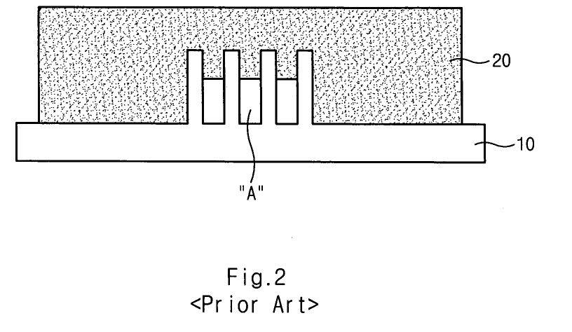

While the disclosed invention is susceptible of embodiments in various forms, there are illustrated in the drawings (and will hereafter be described) specific embodiments of the invention, with the understanding that the disclosure and drawings are intended to be illustrative, and are not intended to limit the invention to the specific embodiments described herein.

### DETAILED DESCRIPTION OF THE PREFERRED EMBODIMENTS

There is provided a liquid composition for immersion lithography that comprises water as a main element and a nonionic surfactant as an additive.

Herein, the above-described surfactant should be transparent to light sources, have a refractive index similar to that of water, and not generate bubbles in the liquid composition for immersion lithography when it was added thereto.

The surfactant satisfying the above described conditions is preferably a nonionic surfactant, and more preferably the nonionic surfactant does not contain aromatic group.

Preferably, the nonionic surfactant is selected from the group consisting of a compound represented by Formula I (shown below), polyvinyl alcohol, a pentaerythritol-based compound, a polymer containing an alkylene oxide and mixtures thereof. 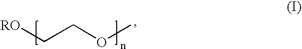
wherein R is a linear or branched, substituted C₁-C₄₀ alkyl, and n is an integer ranging from 10 to 10,000.

Preferably, the surfactant is present in an amount ranging from 0.01 weight percent (wt. %) to 5 wt. %, more preferably from 0.05 wt. % to 1 wt. %, based on total weight of the composition.

A lens is contaminated by the surfactant at exposure when the surfactant exceeds 5 wt. %, and the effect of the surfactant is found insignificant if the surfactant is less than 0.01 wt. %.

Preferably, the compound of Formula I is selected from the group consisting of polyoxyethylene lauryl ether, polyoxyethylene cetyl ether, polyoxyethylene stearyl ether, polyoxyethylene oleyl ether, polyoxyethylene iso-octylcyclohexyl ether, polyoxyethylene sorbitan monolaurate, polyoxyethylene sorbitan monostearate, polyoxyethylene sorbitan trioleate, and mixtures thereof.

Preferably, the polyvinylalcohol has a weight-average molecular weight ranging from 1,000 to 150,000.

Preferably, the pentaerythritol-based compound has a number-average molecular weight ranging from 10 to 10,000.

Preferably, the pentaerythritol-based compound is selected from the group consisting of pentaerythritol ethoxylate, pentaerythritol monooleate and mixtures thereof.

Preferably, the polymer containing an alkylene oxide has a number-average molecular weight ranging from 10 to 20,000.

The alkylene oxide is selected from the group consisting of ethylene oxide, propylene oxide, butylene oxide and combinations thereof. Here, the alkylene oxide is present in an amount ranging from 70 wt. % to 90 wt. %, based on total weight of the polymer.

The effect of the surfactant is degraded when the alkylene oxide is more than 90 wt. %, and the surfactant is not transparent as it was dissolved in water if the akylene oxide is less than 70 wt. %.

The polymer containing the alkylene oxide is polyethylene-block-poly(ethylene glycol) containing 80 wt. % ethylene oxide and having a number-average molecular weight of 2,250, a poly(ethylene glycol)-block-poly(propylene glycol)-block-poly(ethylene glycol) containing 82.5 wt. % ethylene oxide and having a number-average molecular weight of 14,600, or a poly(ethylene glycol)-block-poly(propylene glycol)-block-poly(ethylene glycol) containing 80 wt. % ethylene oxide and having a number-average molecular weight of 8,400.

For example, the polyethylene-block-poly(ethylene glycol) containing 80 wt. % ethylene oxide means that has a content of poly(ethylene glycol) of 80 percent by weight, based on total weight of the polyethylene-block-poly(ethylene glycol).

In the liquid composition, where the water is deionized water, it has a temperature ranging from 20° C. to 25° C., more preferably from 22° C. to 23° C., and is filtered to remove impurities.

In addition, the deionized water where impurities are removed by the filter is mixed with the surfactant, and then re-filtered to obtain the disclosed liquid composition for immersion lithography.

The disclosed liquid composition for immersion lithography comprises the above-described nonionic surfactant, which reduces surface tension of the liquid composition. Therefore, using the present liquid composition, the problem that the liquid composition is not completely filled or is partially concentrated on a wafer having a fine topology as well as on a common wafer is solved, and micro bubbles between a photoresist film and the liquid composition are removed.

Also, there is provided an immersion lithography device comprising an immersion lens unit, a wafer stage and a projection lens unit, wherein the disclosed liquid composition for immersion lithography is used in the immersion lens unit.

The above-described immersion lens unit is configured to have a receiving part, a providing part and a recovering part of the liquid composition for immersion lithography.

A wafer mounted on the wafer stage includes a wafer having a fine topology as well as a common wafer, and the disclosed immersion lithography device is preferably selected from the group consisting of a shower-type device, a bath-type device and a submarine-type device.

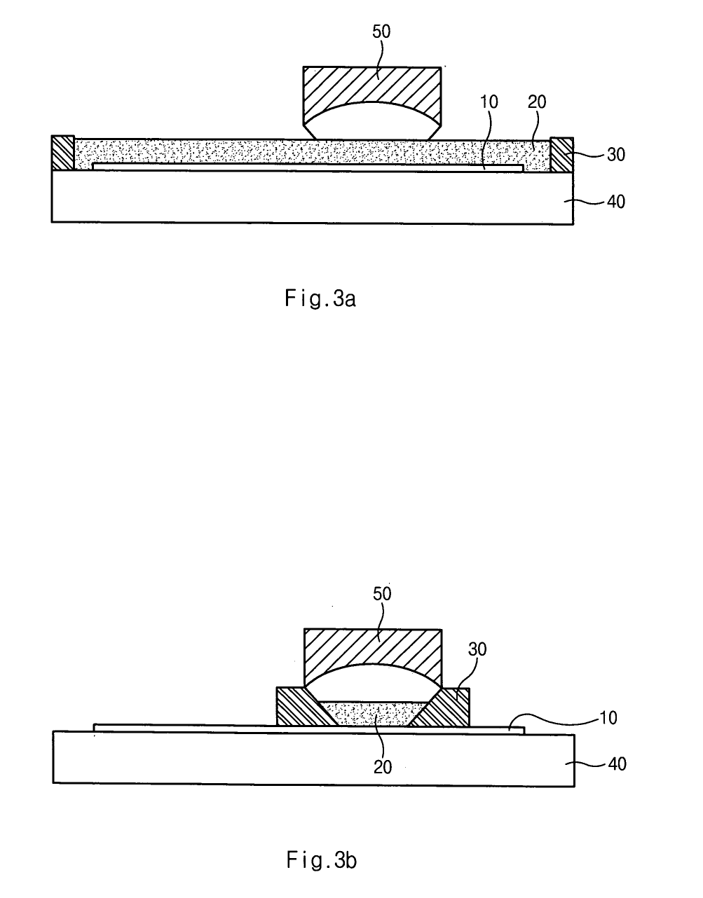

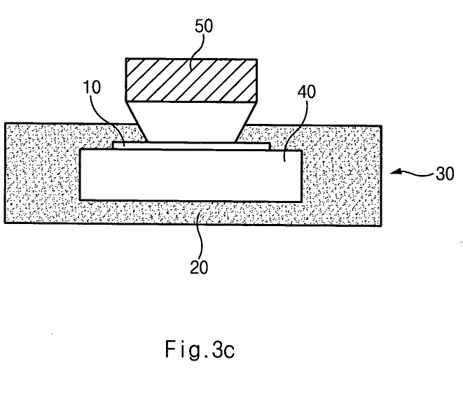

Referring to FIG. 3a, a bath-type immersion lithography device is illustrated which comprises an immersion lens unit 30 so that a liquid composition 20 for immersion lithography covers whole surface of a wafer 10.

Referring to FIG. 3b, a shower-type immersion lithography device is illustrated which comprises an immersion lens unit 30 for receiving the liquid composition 20 for immersion lithography in a lower end of a projection lens unit 50.

Referring to FIG. 3c, a submarine-type immersion lithography device is illustrated which comprises an immersion lens unit 30 where a wafer stage 40 mounted on a wafer 10 is submerged in the liquid composition 20 for immersion lithography.

In addition, there is provided an immersion lithography method using the disclosed liquid composition for immersion lithography.

Also, there is provided a semiconductor device fabricated using the disclosed liquid composition for immersion lithography.

Furthermore, there is provided a method for fabricating a semiconductor device. The method includes providing a wafer, forming a photoresist film on the wafer, exposing the photoresist film using the disclosed liquid composition for immersion lithography, and developing the exposed photoresist film to obtain a photoresist pattern.

The above-described wafer includes a common wafer or a wafer having a fine topology.

Preferably, the exposing step comprises passing a light source through the liquid composition.

Hereinafter, the present invention will be described in more details by referring to examples below, which are not intended to limit the present invention.

### PREPARATION EXAMPLE 1

1 g of polyoxyethylene lauryl ether produced by Aldrich Co., Ltd. (Product Name Name: Brij 35) was dissolved in 500 g of deionized water, thereby obtaining a liquid composition for immersion lithography.

### PREPARATION EXAMPLE 2

1 g of polyoxyethylene cetyl ether produced by Aldrich Co., Ltd. (Product Name: Brij 58) was dissolved in 500 g of deionized water, thereby obtaining a liquid composition for immersion lithography.

### PREPARATION EXAMPLE 3

1 g of polyoxyethylene stearyl ether produced by Aldrich Co., Ltd. (Product Name: Brij 78) was dissolved in 500 g of deionized water, thereby obtaining a liquid composition for immersion lithography.

### PREPARATION EXAMPLE 4

1 g of polyoxyethylene oleyl ether produced by Aldrich Co., Ltd. (Product Name: Brij 98) was dissolved in 500 g of deionized water, thereby obtaining a liquid composition for immersion lithography.

### PREPARATION EXAMPLE 5

1 g of polyoxyethylene iso-octylcyclohexyl ether produced by Aldrich Co., Ltd. (Product Name: Triton X-100) was dissolved in 500 g of deionized water, thereby obtaining a liquid composition for immersion lithography.

### PREPARATION EXAMPLE 6

1 g of polyoxyethylene sorbitan monolaurate produced by Aldrich Co., Ltd. (Product Name: Tween 20) was dissolved in 500 g of deionized water, thereby obtaining a liquid composition for immersion lithography.

### PREPARATION EXAMPLE 7

1 g of polyoxyethylene sorbitan monostearate produced by Aldrich Co., Ltd. (Product Name: Tween 60) was dissolved in 500 g of deionized water, thereby obtaining a liquid composition for immersion lithography.

### PREPARATION EXAMPLE 8

1 g of polyoxyethylene sorbitan monoleate produced by Aldrich Co., Ltd. (Product Name: Tween 80) was dissolved in 500 g of deionized water, thereby obtaining a liquid composition for immersion lithography.

### PREPARATION EXAMPLE 9

1 g of polyoxyethylene sorbitan trioleate produced by Aldrich Co., Ltd. (Product Name: Tween 85) was dissolved in 500 g of deionized water, thereby obtaining a liquid composition for immersion lithography.

### PREPARATION EXAMPLE 10

1 g of polyvinylalcohol having a weight-average molecular weight ranging from 13,000 to 23,000 (Ald #34,840, 98-99 wt. % hydrolyzed) was dissolved in 300 g of deionized water, thereby obtaining a liquid composition for immersion lithography.

### PREPARATION EXAMPLE 11

1 g of polyvinylalcohol having a weight-average molecular weight ranging from 85,000 to 146,000 (Ald #36,314, 98-99% hydrolyzed) was dissolved in 400 g of deionized water, thereby obtaining a liquid composition for immersion lithography.

### PREPARATION EXAMPLE 12

5 g of pentaerythritol ethoxylate having a number-average molecular weight of about 270 (Ald #41,615-0) was dissolved in 300 g of deionized water, thereby obtaining a liquid composition for immersion lithography.

### PREPARATION EXAMPLE 13

5 g of pentaerythritol ethoxylate having a number-average molecular weight of about 797 (Ald #41,873-0) was dissolved in 300 g of deionized water, thereby obtaining a liquid composition for immersion lithography.

### PREPARATION EXAMPLE 14

5 g of pentaerythritol ethoxylate having a number-average molecular weight of about 426 (Ald #41,874-9) was dissolved in 300 g of deionized water, thereby obtaining a liquid composition for immersion lithography.

### PREPARATION EXAMPLE 15

1 g of pentaerythritol monooleate produced by Thornley (Product Name: Spipoest PEMO) was dissolved in 400 g of deionized water, thereby obtaining a liquid composition for immersion lithography.

### PREPARATION EXAMPLE 16

1 g of polyethylene-block-poly(ethylene glycol) (Aldrich #52590-1) containing a 80 wt. % ethylene oxide and having a number-average molecular weight of 2,250 was dissolved in 400 g of deionized water, thereby obtaining a liquid composition for immersion lithography.

### PREPARATION EXAMPLE 17

1 g of poly(ethylene glycol)-block-poly(propylene glycol)-block-poly(ethylene glycol) (Aldrich #54234-2) containing an 82.5 wt. % ethylene oxide and having a number-average molecular weight of 14,600 was dissolved in 400 g of deionized water, thereby obtaining a liquid composition for immersion lithography.

### PREPARATION EXAMPLE 18

1 g of poly(ethylene glycol)-block-poly(propylene glycol)-block-poly(ethylene glycol) (Aldrich #41232-5) containing an 80 wt. % ethylene oxide and having a number-average molecular weight of 8,400 was dissolved in 400 g of deionized water, thereby obtaining a liquid composition for immersion lithography.

### EXAMPLES 1 THROUGH 9

The refractive indices of the liquid compositions for immersion lithography obtained from Preparation Examples 1 through 9 were shown to range from 1.42 to 1.44, which were desirable in the present invention.

### EXAMPLES 10 THROUGH 11

The refractive indices of the liquid compositions for immersion lithography obtained from Preparation Examples 10 and 11 were shown to range from 1.42 to 1.44, which were desirable in the present invention.

### EXAMPLES 12 THROUGH 15

The refractive indices of the liquid compositions for immersion lithography obtained from Preparation Examples 12 through 15 were shown to range from 1.41 to 1.44, which were desirable in the present invention.

### EXAMPLES 16 THROUGH 18

The refractive indices of the liquid compositions for immersion lithography obtained from Preparation Examples 16 through 18 were shown to range from 1.42 to 1.44, which were desirable in the present invention.

As discussed earlier, in an embodiment of the present invention, an immersion lithography process is performed with a liquid composition for immersion lithography comprising a nonionic surfactant as an additive and water as a main element. As a result, the surface tension of the liquid composition is reduced by the nonionic surfactant, thereby solving the problem that the liquid composition is not completely filled or is partially concentrated on a wafer having a fine topology, and removing micro bubbles between the photoresist film and the liquid composition.

The foregoing description is given for clearness of understanding only, and no unnecessary limitations should be understood therefrom, as modification within the scope of the invention may be apparent to those having ordinary skills in the art.

1. A liquid composition for immersion lithography comprising a main element and an additive, wherein the main element is water and the additive is a nonionic surfactant.

2. The liquid composition of claim 1, wherein the nonionic surfactant is selected from the group consisting of a compound represented by Formula I, a polyvinyl alcohol, a pentaerythritol-based compound, a polymer containing an alkylene oxide and mixtures thereof: 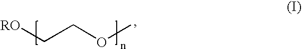
wherein
R is a linear or branched, substituted C₁-C₄₀ alkyl; and
n is an integer ranging from 10 to 10,000.

3. The liquid composition of claim 1, wherein the nonionic surfactant is present in an amount ranging from 0.01 weight percent (wt. %) to 5 wt. %, based on total weight of the composition.

4. The liquid composition of claim 3, wherein the nonionic surfactant is present in an amount ranging from 0.05 wt. % to 1 wt. %, based on total weight of the composition.

5. The liquid composition of claim 2, wherein the compound represented by Formula I is selected from the group consisting of polyoxyethylene lauryl ether, polyoxyethylene cetyl ether, polyoxyethylene stearyl ether, polyoxyethylene oleyl ether, polyoxyethylene iso-octylcyclohexyl ether, polyoxyethylene sorbitan monolaurate, polyoxyethylene sorbitan monostearate, polyoxyethylene sorbitan trioleate, and mixtures thereof.

6. The liquid composition of claim 2, wherein the polyvinylalcohol has a weight-average molecular weight ranging from 1,000 to 150,000.

7. The liquid composition of claim 2, wherein the pentaerythritol-based compound has a number-average molecular weight ranging from 10 to 10,000.

8. The liquid composition of claim 2, wherein the pentaerythritol-based compound is selected from the group consisting of pentaerythritol ethoxylate, pentaerythritol monooleate, and mixtures thereof.

9. The liquid composition of claim 2, wherein the polymer containing an alkylene oxide has a number-average molecular weight ranging from 10 to 20,000.

10. The liquid composition of claim 2, wherein the alkylene oxide is selected from the group consisting of ethylene oxide, propylene oxide, butylene oxide, and combinations thereof.

11. The liquid composition of claim 2, wherein the alkylene oxide is present in an amount ranging from 70 wt. % to 90 wt. %, based on total weight of the polymer.

12. The liquid composition of claim 1, wherein the water is deionized water.

13. An immersion lithography device comprising an immersion lens unit, a wafer stage and a projection lens unit, wherein the liquid composition of claim 1 is used in the immersion unit.

14. The immersion lithography device of claim 13, wherein the device is selected from the group consisting of a shower-type device, a bath-type device and a submarine-type device.

15. The immersion lithography device according to claim 13, further comprising a wafer mounted on the wafer stage, the wafer having a fine topology.

16. An immersion lithography method using the liquid composition of claim 1.

17. A method of fabricating a semiconductor device, the method comprising:
(a) providing a wafer;
(b) forming a photoresist film on the wafer;
(c) exposing the photoresist film using a liquid composition of claim 1; and
(d) developing the exposed photoresist film to obtain a photoresist pattern.

18. The method of claim 17, wherein the wafer has a fine topology.

19. The method of claim 17, wherein step (c) comprises passing a light source through the liquid composition.

20. A semiconductor device made by a method comprising:
(a) providing a wafer;
(b) forming a photoresist film on the wafer;
(c) exposing the photoresist film using a liquid composition of claim 1; and
(d) developing the exposed photoresist film to obtain a photoresist pattern.
